(19) United States
(12) Patent Application Publication
(10) Pub. No.: US 2026/0206255 A1
(43) Pub. Date: Jul. 16, 2026

(54) SILICON CARBIDE MOSFET WITH STRETCHED CONTACT AREA

(71) Applicant: Renesas Electronics Corporation, Tokyo (JP)

(72) Inventors: Kijeong HAN, Morrisville, NC (US); Meng Chia LEE, Dallas, TX (US); Dilip Madhav RISBUD, San Jose, CA (US)

(73) Assignee: Renesas Electronics Corporation, Tokyo (JP)

(21) Appl. No.: 19/015,989

(22) Filed: Jan. 10, 2025

(51) Int. Cl. H10D 30/66; H10D 30/01; H10D 62/13; H10D 62/832

(52) U.S. Cl. CPC H10D 30/66; H10D 30/0291; H10D 62/153; H10D 62/8325

(57) ABSTRACT

A semiconductor structure includes a gate electrode disposed above a semiconductor substrate of a first conductivity type. The semiconductor structure further includes a source region of the first conductivity type positioned, at least partially, below the gate electrode, and a doped region of a second conductivity type, opposite to the first conductivity type, located adjacent to the source region. The semiconductor structure further includes a first ohmic contact positioned above and in contact with the source region and the doped region. The first ohmic contact having a length and a contact area in electrical communication with the doped region. The semiconductor structure further includes a field oxide adjacent to the doped region, with the length of the first ohmic contact extending above the doped region until a distance between the first ohmic contact and the field oxide is equal to a threshold value.

### BACKGROUND

The present disclosure generally relates to the field of semiconductor devices, and more particularly to planar silicon carbide metal-oxide-semiconductor field-effect transistors.

The rapid advancement of power electronics has created a growing demand for high-performance semiconductor devices capable of operating at elevated voltages, temperatures, and frequencies. Metal-oxide-semiconductor field-effect transistors (MOSFETs) are integral components in modern power conversion and management systems, utilized in applications ranging from electric vehicles and renewable energy systems to industrial motor drives.

Among the various semiconductor materials, silicon carbide (SiC) has gained significant attention due to its superior properties, such as a wide bandgap, high thermal conductivity, and excellent electric field breakdown strength. These characteristics make SiC an ideal candidate for high-voltage and high-temperature applications, outperforming traditional silicon-based devices in terms of efficiency and thermal performance.

However, the design and fabrication of SiC MOSFETs come with unique challenges. Traditional planar MOSFET structures may often suffer from issues related to elevated sheet resistance. This can lead to voltage drops, parasitic conduction, power losses, reduced current handling, latch-up, and overall decreased reliability. To address these limitations, innovative designs are necessary to improve the robustness and performance of planar SiC MOSFETs.

### SUMMARY

According to an embodiment of the present disclosure, a semiconductor structure includes a gate electrode disposed above a semiconductor substrate of a first conductivity type, a source region of the first conductivity type positioned, at least partially, below the gate electrode, a doped region of a second conductivity type, opposite to the first conductivity type, adjacent to the source region, a first ohmic contact positioned above and in contact with the source region and the doped region, with the first ohmic contact having a length and a contact area in electrical communication with the doped region, and a field oxide adjacent to the doped region, with the length of the first ohmic contact extending above the doped region until a distance between the first ohmic contact and the field oxide is equal to a threshold value.

According to another embodiment of the present disclosure, a semiconductor structure includes a semiconductor substrate of a first conductivity type having an upper surface and a bottom surface, the semiconductor substrate including a silicon carbide substrate, a drift region of the first conductivity type located on the upper surface of the semiconductor substrate, a channel region of a second conductivity type, opposite to the first conductivity type, located above the drift region, a source region of the first conductivity type adjacent to the channel region, a doped region of the second conductivity type adjacent to the source region, a gate electrode disposed above the source region via a gate oxide, a first ohmic contact positioned above and in contact with the source region and the doped region, with the first ohmic contact having a length and a contact area in electrical communication with the doped region, and a field oxide adjacent to the doped region, with the length of the first ohmic contact extending above the doped region until a distance between the first ohmic contact and the field oxide is equal to a threshold value.

According to yet another embodiment of the present disclosure, a method of forming a semiconductor structure includes forming a gate electrode above a semiconductor substrate of a first conductivity type, forming a source region of the first conductivity type partially below the gate electrode, forming a doped region of a second conductivity type, opposite to the first conductivity type, adjacent to the source region, forming a first ohmic contact above and in contact with the source region and the doped region, with the first ohmic contact having a length and a contact area in electrical communication with the doped region, and forming a field oxide adjacent to the doped region, with the length of the first ohmic contact extending above the doped region until a distance between the first ohmic contact and the field oxide is equal to a threshold value.

### BRIEF DESCRIPTION OF THE DRAWINGS

The following detailed description, given by way of example and not intended to limit the embodiments described herein, will best be appreciated in conjunction with the accompanying drawings, in which:

FIG. 1 illustrates a cross-sectional view of a portion of a semiconductor structure, according to an embodiment of the present disclosure;

FIG. 2A illustrates a simplified top-down view of the semiconductor structure, according to an embodiment of the present disclosure;

FIG. 2B illustrates a detailed top-down view of a portion of the semiconductor structure, as depicted in FIG. 2A, according to an embodiment of the present disclosure;

FIG. 3A illustrates a simplified top-down view of the semiconductor structure, according to an embodiment of the present disclosure;

FIG. 3B illustrates a detailed top-down view of a portion of the semiconductor structure, as depicted in FIG. 3A, according to an embodiment of the present disclosure;

FIG. 4A illustrates a simplified top-down view of the semiconductor structure, according to an embodiment of the present disclosure;

FIG. 4B illustrates a detailed top-down view of a portion of the semiconductor structure, as depicted in FIG. 4A, according to an embodiment of the present disclosure;

FIG. 5A illustrates a simplified top-down view of the semiconductor structure, according to an embodiment of the present disclosure;

FIG. 5B illustrates a detailed top-down view of a portion of the semiconductor structure, as depicted in FIG. 5A, according to an embodiment of the present disclosure;

FIG. 6A illustrates a simplified top-down view of the semiconductor structure, according to an embodiment of the present disclosure;

FIG. 6B illustrates a detailed top-down view of a portion of the semiconductor structure, as depicted in FIG. 6A, according to an embodiment of the present disclosure; and

FIG. 7 illustrates a flowchart depicting operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In silicon carbide (SiC) semiconductor devices, formation of P-type regions typically involves aluminum (Al) implantation. However, the resulting sheet resistance of these P-type regions may often be high due to poor implant activation rates. Despite high aluminum doses, the elevated sheet resistance can lead to significant voltage drops across the P-type regions when current flows through them. When the voltage drops exceed the built-in potential between adjacent P-type and N-type regions, a parasitic internal P-N diode can conduct unexpectedly large currents, which can disrupt the device's normal operation.

In planar SiC MOSFETs, the presence of an inherent parasitic N-P-N bipolar junction transistor (BJT) further exacerbates this issue. Under conditions such as avalanche breakdown, the voltage drop can trigger latch-up of the N-P-N BJT, resulting in severe device failure. To mitigate these problems, it is key to design and implement sufficiently large highly doped P-type contact regions, also called P+ contact regions. These P+ contact regions are necessary to reduce current crowding and voltage drops, ensuring reliable operation and preventing adverse latch-up events.

Therefore, embodiments of the present disclosure provide a SiC planar MOSFET device layout including a stretched or extended P+contact region that can enhance device robustness by preventing N-P-N latch-up failure modes during reliability tests, such as the Unclamped Inductive Switching (UIS) and Short circuit tests. In the proposed device layout, the P+ contact area is larger than in traditional planar MOSFET designs, which helps to distribute current more evenly and reduce voltage drops. Furthermore, the stretched P+ contact layout is less sensitive to poor P+ contact resistance, as it mitigates current crowding, which is a common cause of high voltage drops. Importantly, the larger P+ contact area may not significantly consume the active device area, meaning that the overall device characteristics remain nearly the same.

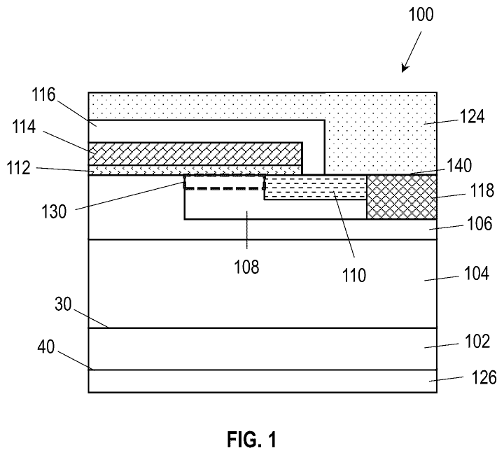

Embodiments by which the SiC planar MOSFET with stretched P+ contact region can be formed is described in detail below by referring to the accompanying drawings in FIGS. 1-6.

FIG. 1 is a cross-sectional view of a portion of a semiconductor structure 100, according to an embodiment of the present disclosure. In this embodiment, semiconductor structure 100 is a SiC planar MOSFET structure.

As depicted in the figure, semiconductor structure 100 can include a semiconductor substrate (hereinafter “substrate”) 102 of a first conductivity type that is made of silicon carbide (SiC). A thickness of the initial substrate 102 can be approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type. In the depicted embodiment, the first conductivity type is N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 30 and a bottom surface 40.

A bottom metal layer 126 can be formed on the bottom surface 40 of the substrate 102. The bottom metal layer 126 serves as a drain terminal or drain electrode that provides electrical (ohmic) contact with substrate 102.

A drift region 104 of the first conductivity type can be formed on the upper surface 30 of the substrate 102. The drift region 104 is made of silicon carbide with an added impurity concentration that is lower than the impurity concentration of substrate 102. Drift region 104 can be a region where carriers (e.g., electrons or holes) can drift from source region 110 to drain region or substrate 102. In general, drift region 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift region 104 can be formed by chemical vapor deposition (CVD) of the semiconductor material (i.e., SiC).

A thickness of the drift region 104 can be determined by the device voltage rating. For example, the thickness of the drift region 104 can be approximately 10 μm for 1.2 kV rated devices. The impurity concentration of the drift region 104 can be approximately 1×10¹⁶ cm⁻³ for 1.2 kV rated devices. However, the impurity concentration of the drift region 104 is not limited to this value and may be in a range of approximately 1×10¹⁴ cm⁻³ to approximately 1×10¹⁷ cm⁻³ depending on the device voltage rating.

A JFET region 106 can be formed above and in contact with the drift region 104. In some instances, JFET region 106 can be formed with a higher donor doping of the first conductivity type that can vary between approximately 1×10¹⁵ cm⁻³ and approximately 1×10¹⁸ cm⁻³. A thickness of the JFET region 106 can be approximately 0.1 μm to approximately 3.5 μm.

A base region 108, including a doped semiconductor region of a second conductivity type, can be formed above and in contact with the JFET region 106. A thickness of the base region 108 can be approximately 0.1 μm to approximately 1.0 μm. The impurity concentration of the base region 108 can vary between approximately 1×10¹⁹ cm⁻³ to approximately 1×10²¹ cm⁻³. The second conductivity type can be P-type or N-type. Generally, the second conductivity type is opposite to the first conductivity type. Thus, in the depicted embodiment, the second conductivity type is P-type. In an embodiment, a channel region 130 of the second conductivity type is formed within base region 108. Channel region 130 is in contact with JFET region 106 and adjacent to source region 110 and doped region 118.

Source region 110 can be formed above and in contact with base region 108. A thickness of the source region 110 is approximately 0.1 μm to approximately 0.5 μm. Source region 110 may include a heavily-doped semiconductor layer of the first conductivity type. A dopant concentration of source region 110 can vary, for example, between 1×10¹⁹ cm⁻³ and 1×10²¹ cm⁻³.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor layers.

With continued reference to FIG. 1, doped region 118 can be formed above and in contact with JFET region 106 and adjacent to base region 108 and source region 110. Doped region 118 includes a semiconductor region composed of a heavily doped silicon carbide layer of the second conductivity type. An ion implantation process can be conducted on the semiconductor structure 100 to form doped region 118. Doped region 118 can be formed with an impurity concentration of the second conductivity type varying between approximately 1×10¹⁹ cm⁻³ and approximately 1×10²¹ cm⁻³. In embodiments in which the second conductivity type is P-type, doped region 118 can be referred to as P+ region. A thickness of doped region 118 can vary between approximately 0.1 μm and approximately 3.5 μm. In one or more embodiments, doped region 118 may allow for the separation of P+ and N+ contacts which can increase P+ contact area and minimize the risk of N-P-N latch-up during UIS and short-circuit tests.

With continued reference to FIG. 1, a gate oxide 112 can be formed above doped region 118, base region 108 and source region 110 using various types of deposition processes. The gate oxide 112 can electrically separate a subsequently formed gate electrode 114 from active areas of the semiconductor structure 100. In one or more embodiments, gate oxide 112 can be formed by conformal deposition of a gate insulating film. Non-limiting examples of gate insulating films to form gate oxide 112 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO2) and the like. In an exemplary embodiment, a thickness of the gate oxide 112 can vary between approximately 10 nm to approximately 100 nm.

The process of forming gate electrode 114 usually includes depositing a conductive material, such as polysilicon, above the gate oxide 112. The gate electrode 114 and gate oxide 112 provide a gate structure for the semiconductor structure 100. After forming the gate electrode 114, an interlevel dielectric layer 116 can be formed to fill voids and electrically isolate active regions within the semiconductor structure 100. The interlevel dielectric layer 116 is disposed above the gate electrode 114. More particularly, the interlevel dielectric layer 116 covers an upper surface and opposite sidewalls of gate electrode 114, opposite sidewalls of gate oxide 112, and partially covers an upper surface of source region 110. In one or more embodiments, the interlevel dielectric layer 116 can be formed by, for example, conformal deposition (e.g., CVD) of a dielectric material such as silicon oxide, silicon nitride, and the like. In one or more embodiments, a patterning process can be conducted on the interlevel dielectric layer 116 to achieved the shape shown in the figures.

A top metal layer 124 can be deposited above the interlevel dielectric layer 116 and above exposed portions of source region 110 and doped region 118. The top metal layer 124 provides a source terminal or source electrode (ohmic contact) that electrically contacts source region 110 and doped region 118.

In the proposed embodiment, top metal layer 124 includes a stretched or extended contact area 140 positioned between the top metal layer 124, doped region 118, and source region 110. For easy of illustration, the top metal layer 124 having extended contact area 140 will be referred to as first ohmic contact 124, while bottom metal layer 126 will be referred to as second ohmic contact 126. In this embodiment, the contact area 140 can be made larger than that of traditional planar MOSFETs by increasing a length of first ohmic contact 124. Increasing the length of the first ohmic contact 124, and thus the contact area 140, can help to distribute current more evenly and reduce voltage drops. Thus, embodiments of the present disclosure provides a layout design adjustment in which an insulating field oxide (FOX) layer is pushed out (thinning or shifting) to make more room for the extended ohmic contact area, as will be described in detail below. By doing this, the device active area, where the semiconductor functions, remains unchanged and unaffected, meaning the device's performance and functionality are preserved.

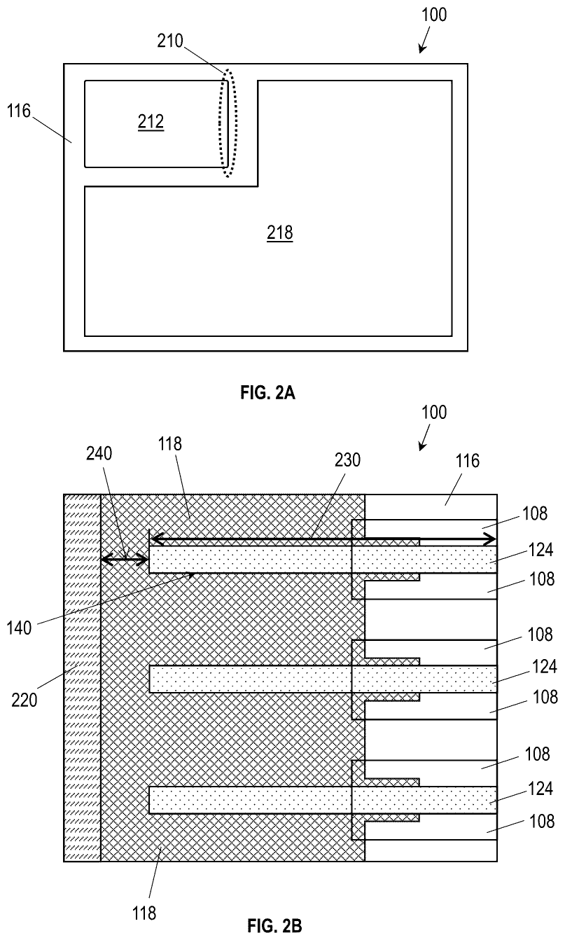

FIG. 2A is a simplified top-down view of the semiconductor structure 100, according to an embodiment of the present disclosure. FIG. 2B provides a detailed top-down view of a portion 210 of the semiconductor structure 100, as depicted in FIG. 2A, according to an embodiment of the present disclosure. It should be noted that the description of FIGS. 2A-2B can refer to components shown in FIG. 1.

In an embodiment, gate electrode 114 can be positioned in a corner portion of the semiconductor structure 100 and may act as a gate pad 212, as depicted in FIG. 2A. Source pad 218, located directly on the source region 110, can be arranged next to gate pad 212. Both the gate pad 212 and the source pad 218 are configured to provide electrical contact to an external device or element.

FIG. 2B provides a detailed view of the portion 210 located on a right edge of gate pad 212. In this view, the extended contact area 140 between first ohmic contact 124 and doped region 118 can be appreciated. Specifically, a length 230 of the first ohmic contact 124 can be stretched or extended to increase the contact area 140 between first ohmic contact 124 and doped region 118. For instance, the length 230 of the first ohmic contact 124 can be extended from approximately 1 mm to approximately 10 mm, or ranges therebetween, in order to increase the contact region 140. In this embodiment, the length 230 of the first ohmic contact 124 can be stretched based on maintaining a distance 240 of at least 2 mm between first ohmic contact 124 and field oxide 220. In one or more embodiments, field oxide 220 can be a thick, insulating layer of silicon dioxide (SiO₂) that is typically grown or deposited on the wafer's surface to isolate different regions of the semiconductor structure 100, especially active areas such as channel region 130. In an embodiment, a layer of field oxide 220 may have a thickness varying from approximately 5,000 Å to approximately 20,000 Å. Accordingly, expanding the length 230 of the first ohmic contact 124, while maintaining the distance 240 between the first ohmic contact 124 and the field oxide 220 at or above a minimum threshold value, can facilitate layout design and help prevent short circuits, ensure proper gate control, and minimize parasitic capacitance. It should be noted that in FIG. 2B, base region 108 is included for reference, while the gate electrode 114 has been omitted from this view to better facilitate the description of the embodiments. However, it may be understood that there is no overlap between first ohmic contact 124 and gate electrode 114, as shown in FIG. 1.

It is important to note that field oxide 220 is distinct from the (thin) gate oxide 112, which directly interfaces with the gate electrode 114. While both are forms of SiO₂, they perform different functions within the device architecture. More particularly, field oxide 220 isolates transistors within a circuit, gate oxide 112 controls the transistor operation, and interlevel dielectric layer 116 separates different metal layers on the semiconductor structure 100.

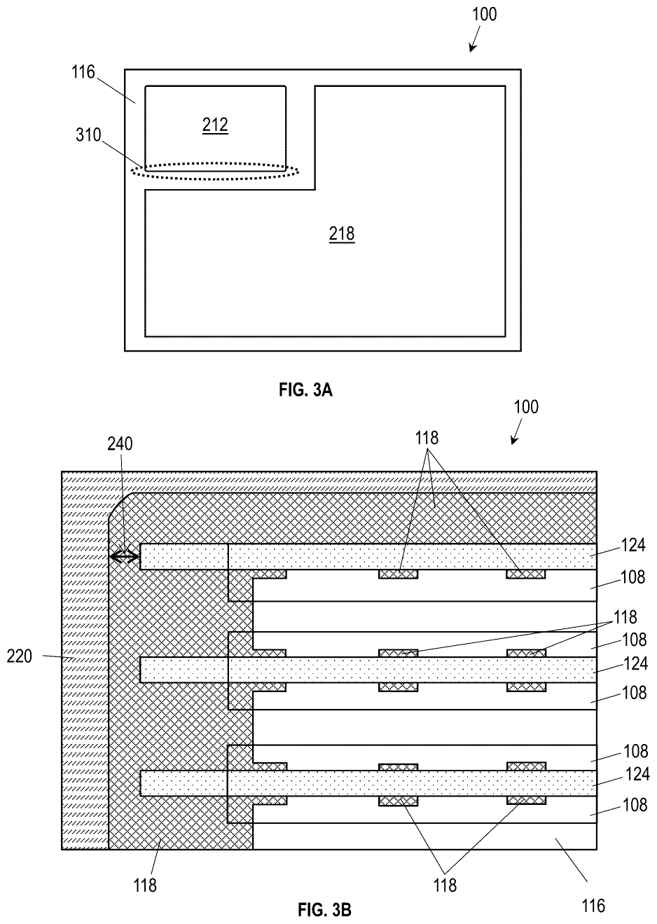

FIG. 3A is a simplified top-down view of the semiconductor structure 100, according to an embodiment of the present disclosure. FIG. 3B provides a detailed top-down view of a portion 310 located on a bottom edge of gate pad 212, as depicted in FIG. 3A, according to an embodiment of the present disclosure. It should be noted that the description of FIGS. 3A-3B can refer to components shown in FIG. 1, FIG. 2A, and FIG. 2B.

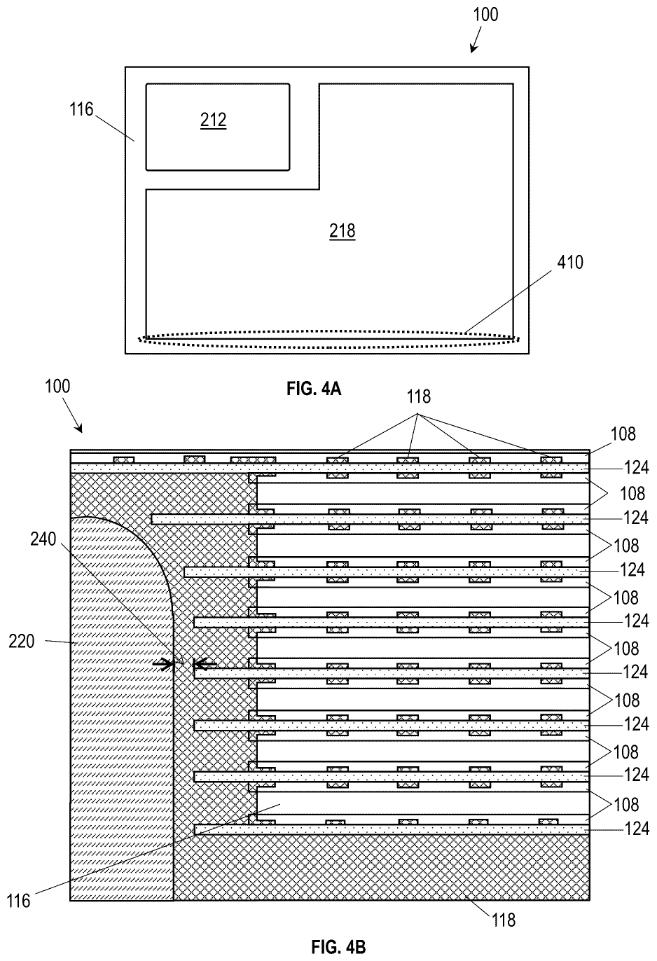

FIG. 4A is a simplified top-down view of the semiconductor structure 100, according to an embodiment of the present disclosure. FIG. 4B provides a detailed top-down view of a portion 410 positioned on a bottom edge of source pad 218, as depicted in FIG. 4A, according to an embodiment of the present disclosure. It should be noted that the description of FIGS. 4A-4B can refer to components shown in FIG. 1, FIG. 2A, FIG. 2B, FIG. 3A, and FIG. 3B.

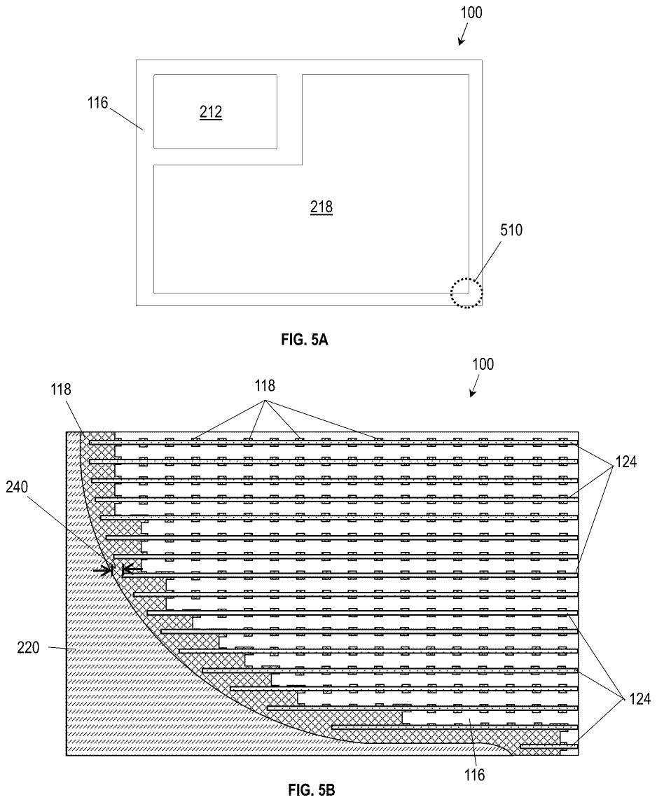

FIG. 5A is a simplified top-down view of the semiconductor structure 100, according to an embodiment of the present disclosure. FIG. 5B provides a detailed top-down view of a portion 510 positioned on a right-bottom corner of source pad 218, as depicted in FIG. 5A, according to an embodiment of the present disclosure. It should be noted that the description of FIGS. 5A-5B can refer to components shown in FIG. 1, FIG. 2A, FIG. 2B, FIG. 3A, FIG. 3B, FIG. 4A, and FIG. 4B.

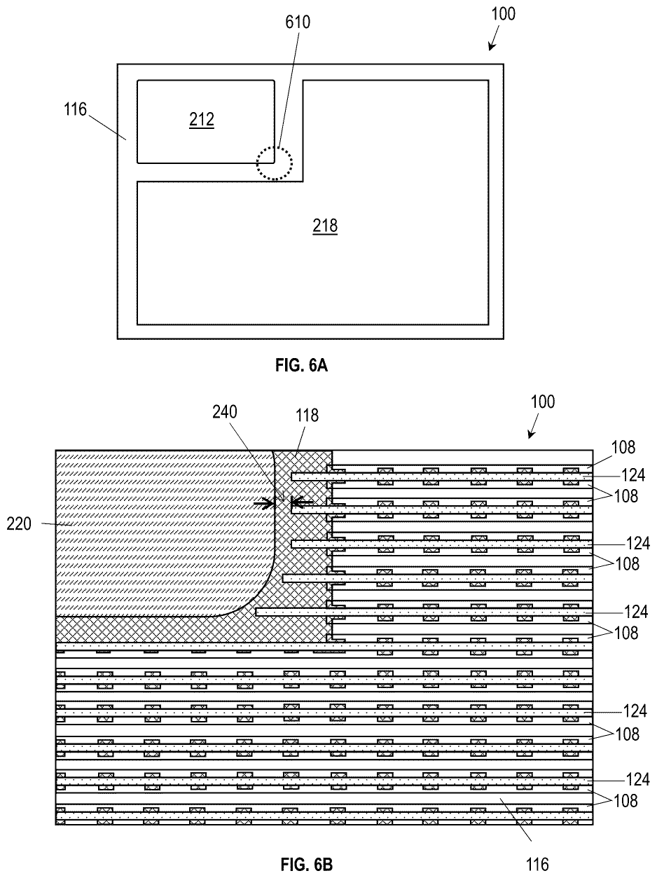

FIG. 6A is a simplified top-down view of the semiconductor structure 100, according to an embodiment of the present disclosure. FIG. 6B provides a detailed top-down view of a portion 610 positioned on a bottom-right corner of gate pad 212, as depicted in FIG. 6A, according to an embodiment of the present disclosure. It should be noted that the description of FIGS. 6A-6B can refer to components shown in FIG. 1, FIG. 2A, FIG. 2B, FIG. 3A, FIG. 3B, FIG. 4A, FIG. 4B, FIG. 5A, and FIG. 5B.

The various views of semiconductor structure 100 depicted in FIGS. 3A-6B illustrate the position of the stretched first ohmic contact 124. As shown in FIGS. 3A-6B, the extended length of first ohmic contact 124 increases the contact area 140 between the first ohmic contact 124 and the doped region 118 (i.e., the P+ doped region). As mentioned previously, base region 108 is included for reference, while the gate electrode 114 has been omitted from these views to better facilitate the description of the embodiments. In each detailed top-down view, the extended first ohmic contact 124 does not reach the field oxide 220, thereby reducing the likelihood of short circuits with the active regions of the semiconductor structure 100, particularly the gate electrode 114. As a result, the larger P+contact area, caused by the extended length of the first ohmic contact 124, does not significantly reduce the active device area, ensuring that the overall device real estate remains largely unaffected.

The distance 240 between the field oxide 220 and the first ohmic contact 124 represents a critical design constraint that must be maintained. The distance 240 directly influences a maximum length that the first ohmic contact 124 can extend, as it impacts the overall performance and reliability of the device. In some embodiments, reducing the thickness of the field oxide 220 can help increase the length 230 of the first ohmic contact 124. This adjustment allows for a larger contact area 140, which can further improve the device's performance by enhancing current handling and reducing resistive losses.

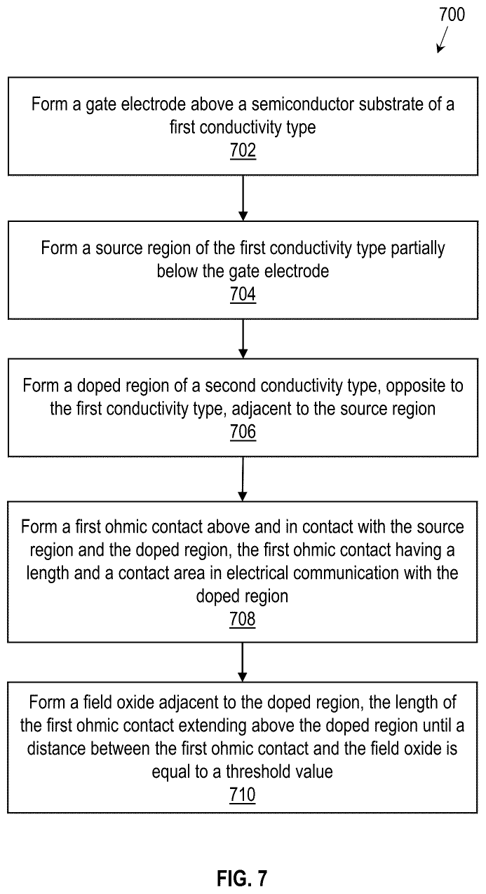

FIG. 7 is a flowchart 700 depicting operational steps for the fabrication of the semiconductor structure 100, according to an embodiment of the present disclosure.

The process starts at step 702 by forming a gate electrode above a semiconductor substrate of a first conductivity type. The semiconductor substrate includes a silicon carbide substrate having an upper surface and a bottom surface.

The process continues at step 704 by forming a source region of the first conductivity type partially below the gate electrode. In an embodiment, an interlevel dielectric layer is formed above the gate electrode, partially extending above a top surface of the source region.

The process continues at step 706 in which a doped region of a second conductivity type, opposite to the first conductivity type, is formed adjacent to the source region.

The process continues at step 708 by forming a first ohmic contact above and in contact with the source region and the doped region. In an embodiment, the first ohmic contact has a length and respective contact area in electrical communication with the doped region. In an embodiment, the first ohmic contact is disposed above the interlevel dielectric layer.

Finally, at step 710, a field oxide is formed adjacent to the doped region. In an embodiment, the length of the first ohmic contact extends above the doped region until a distance between the first ohmic contact and the field oxide is equal to a threshold value. In an embodiment, the threshold value corresponds to a minimum distance between the first ohmic contact and the field oxide. In embodiment, the minimum distance between the first ohmic contact and the field oxide can be at least 2 mm. In an embodiment, the length of the first ohmic contact extending above the doped region can be at least 1 mm.

In one or more embodiments, a drift region of the first conductivity type is formed on the upper surface of the semiconductor substrate. Above the drift region, a JFET region of the first conductivity type is formed. Between the JFET region and the source region, a base region of the second conductivity type is formed. A gate oxide is deposited over the JFET region, base region, and source region. A channel region of the second conductivity type is formed on top of the base region and beneath the gate oxide. Finally, a second ohmic contact is formed in electrical communication with the bottom surface of the semiconductor substrate.

### EXAMPLES

Example 1. A semiconductor structure, comprising:
a gate electrode disposed above a semiconductor substrate of a first conductivity type;
a source region of the first conductivity type positioned, at least partially, below the gate electrode;
a doped region of a second conductivity type, opposite to the first conductivity type, adjacent to the source region;
a first ohmic contact positioned above and in contact with the source region and the doped region, wherein the first ohmic contact has a length and a contact area in electrical communication with the doped region; and
a field oxide adjacent to the doped region, wherein the length of the first ohmic contact extends above the doped region until a distance between the first ohmic contact and the field oxide is equal to a threshold value.

Example 2. The semiconductor structure according to Example 1, further comprising:
an interlevel dielectric layer disposed above the gate electrode and partially extending above a top surface of the source region, wherein the first ohmic contact is disposed above the interlevel dielectric layer.

Example 3. The semiconductor structure according to Example 1, wherein the threshold value corresponds to a minimum distance between the first ohmic contact and the field oxide.

Example 4. The semiconductor structure according to Example 3, wherein the minimum distance between the first ohmic contact and the field oxide is at least 2 mm.

Example 5. The semiconductor structure according to Example 1, wherein the length of the first ohmic contact extending above the doped region is at least 1 mm.

Example 6. The semiconductor structure according to Example 1, wherein the semiconductor substrate includes a silicon carbide substrate having an upper surface and a bottom surface.

Example 7. The semiconductor structure according to Example 6, further comprising:
a drift region of the first conductivity type located on the upper surface of the semiconductor substrate;
a JFET region of the first conductivity type located above the drift region;
a base region of the second conductivity type disposed between the JFET region and the source region;
a gate oxide disposed above the JFET region, base region, and source region;
a channel region of the second conductivity type located on the base region and below the gate oxide; and
a second ohmic contact in electrical communication with the bottom surface of the semiconductor substrate.

Example 8. A semiconductor structure, comprising:
a semiconductor substrate of a first conductivity type having an upper surface and a bottom surface, the semiconductor substrate including a silicon carbide substrate;
a drift region of the first conductivity type located on the upper surface of the semiconductor substrate;
a channel region of a second conductivity type, opposite to the first conductivity type, located above the drift region;
a source region of the first conductivity type adjacent to the channel region;
a doped region of the second conductivity type adjacent to the source region;
a gate electrode disposed above the source region via a gate oxide;
a first ohmic contact positioned above and in contact with the source region and the doped region, wherein the first ohmic contact has a length and a contact area in electrical communication with the doped region; and
a field oxide adjacent to the doped region, wherein the length of the first ohmic contact extends above the doped region until a distance between the first ohmic contact and the field oxide is equal to a threshold value.

Example 9. The semiconductor structure according to Example 8, further comprising:
an interlevel dielectric layer disposed above the gate electrode and partially extending above a top surface of the source region, wherein the first ohmic contact is disposed above the interlevel dielectric layer.

Example 10. The semiconductor structure according to Example 8, wherein the threshold value corresponds to a minimum distance between the first ohmic contact and the field oxide.

Example 11. The semiconductor structure according to Example 10, wherein the minimum distance between the first ohmic contact and the field oxide is at least 2 mm.

Example 12. The semiconductor structure according to Example 8, wherein the length of the first ohmic contact extending above the doped region is at least 1 mm.

Example 13. The semiconductor structure according to Example 8, further comprising:
a JFET region of the first conductivity type located above the drift region;
a base region of the second conductivity type disposed between the JFET region and the source region, wherein the channel region is located on the base region, below the gate electrode; and
a second ohmic contact in electrical communication with the bottom surface of the semiconductor substrate.

Example 14. A method of forming a semiconductor structure, comprising:
forming a gate electrode above a semiconductor substrate of a first conductivity type;
forming a source region of the first conductivity type partially below the gate electrode;
forming a doped region of a second conductivity type, opposite to the first conductivity type, adjacent to the source region;
forming a first ohmic contact above and in contact with the source region and the doped region, wherein the first ohmic contact has a length and a contact area in electrical communication with the doped region; and
forming a field oxide adjacent to the doped region, wherein the length of the first ohmic contact extends above the doped region until a distance between the first ohmic contact and the field oxide is equal to a threshold value.

### Example 15. the Method According to Example 14, Further Comprising:

forming an interlevel dielectric layer above the gate electrode and partially extending above a top surface of the source region, wherein the first ohmic contact is disposed above the interlevel dielectric layer.

Example 16. The method according to Example 14, wherein the threshold value corresponds to a minimum distance between the first ohmic contact and the field oxide.

Example 17. The method according to Example 16, wherein the minimum distance between the first ohmic contact and the field oxide is at least 2 mm.

Example 18. The method according to Example 14, wherein the length of the first ohmic contact extending above the doped region is at least 1 mm.

Example 19. The method according to Example 14, wherein the semiconductor substrate includes a silicon carbide substrate having an upper surface and a bottom surface.

Example 20. The method according to Example 19, further comprising:
forming a drift region of the first conductivity type on the upper surface of the semiconductor substrate;
forming a JFET region of the first conductivity type above the drift region;
forming a base region of the second conductivity type between the JFET region and the source region;
forming a gate oxide above the JFET region, base region, and source region;
forming a channel region of the second conductivity type on the base region and below the gate oxide; and
forming a second ohmic contact in electrical communication with the bottom surface of the semiconductor substrate.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a gate electrode disposed above a semiconductor substrate of a first conductivity type;
a source region of the first conductivity type positioned, at least partially, below the gate electrode;
a doped region of a second conductivity type, opposite to the first conductivity type, adjacent to the source region;
a first ohmic contact positioned above and in contact with the source region and the doped region, wherein the first ohmic contact has a length and a contact area in electrical communication with the doped region; and
a field oxide adjacent to the doped region, wherein the length of the first ohmic contact extends above the doped region until a distance between the first ohmic contact and the field oxide is equal to a threshold value.

2. The semiconductor structure according to claim 1, further comprising:
an interlevel dielectric layer disposed above the gate electrode and partially extending above a top surface of the source region, wherein the first ohmic contact is disposed above the interlevel dielectric layer.

3. The semiconductor structure according to claim 1, wherein the threshold value corresponds to a minimum distance between the first ohmic contact and the field oxide.

4. The semiconductor structure according to claim 3, wherein the minimum distance between the first ohmic contact and the field oxide is at least 2 mm.

5. The semiconductor structure according to claim 1, wherein the length of the first ohmic contact extending above the doped region is at least 1 mm.

6. The semiconductor structure according to claim 1, wherein the semiconductor substrate includes a silicon carbide substrate having an upper surface and a bottom surface.

7. The semiconductor structure according to claim 6, further comprising:
a drift region of the first conductivity type located on the upper surface of the semiconductor substrate;
a JFET region of the first conductivity type located above the drift region;
a base region of the second conductivity type disposed between the JFET region and the source region;
a gate oxide disposed above the JFET region, base region, and source region;
a channel region of the second conductivity type located on the base region and below the gate oxide; and
a second ohmic contact in electrical communication with the bottom surface of the semiconductor substrate.

8. A semiconductor structure, comprising:
a semiconductor substrate of a first conductivity type having an upper surface and a bottom surface, the semiconductor substrate including a silicon carbide substrate;
a drift region of the first conductivity type located on the upper surface of the semiconductor substrate;
a channel region of a second conductivity type, opposite to the first conductivity type, located above the drift region;
a source region of the first conductivity type adjacent to the channel region;
a doped region of the second conductivity type adjacent to the source region;
a gate electrode disposed above the source region via a gate oxide;
a first ohmic contact positioned above and in contact with the source region and the doped region, wherein the first ohmic contact has a length and a contact area in electrical communication with the doped region; and
a field oxide adjacent to the doped region, wherein the length of the first ohmic contact extends above the doped region until a distance between the first ohmic contact and the field oxide is equal to a threshold value.

9. The semiconductor structure according to claim 8, further comprising:
an interlevel dielectric layer disposed above the gate electrode and partially extending above a top surface of the source region, wherein the first ohmic contact is disposed above the interlevel dielectric layer.

10. The semiconductor structure according to claim 8, wherein the threshold value corresponds to a minimum distance between the first ohmic contact and the field oxide.

11. The semiconductor structure according to claim 10, wherein the minimum distance between the first ohmic contact and the field oxide is at least 2 mm.

12. The semiconductor structure according to claim 8, wherein the length of the first ohmic contact extending above the doped region is at least 1 mm.

13. The semiconductor structure according to claim 8, further comprising:
a JFET region of the first conductivity type located above the drift region;
a base region of the second conductivity type disposed between the JFET region and the source region, wherein the channel region is located on the base region, below the gate electrode; and
a second ohmic contact in electrical communication with the bottom surface of the semiconductor substrate.

14. A method of forming a semiconductor structure, comprising:
forming a gate electrode above a semiconductor substrate of a first conductivity type;
forming a source region of the first conductivity type partially below the gate electrode;
forming a doped region of a second conductivity type, opposite to the first conductivity type, adjacent to the source region;
forming a first ohmic contact above and in contact with the source region and the doped region, wherein the first ohmic contact has a length and a contact area in electrical communication with the doped region; and
forming a field oxide adjacent to the doped region, wherein the length of the first ohmic contact extends above the doped region until a distance between the first ohmic contact and the field oxide is equal to a threshold value.

15. The method according to claim 14, further comprising:
forming an interlevel dielectric layer above the gate electrode and partially extending above a top surface of the source region, wherein the first ohmic contact is disposed above the interlevel dielectric layer.

16. The method according to claim 14, wherein the threshold value corresponds to a minimum distance between the first ohmic contact and the field oxide.

17. The method according to claim 16, wherein the minimum distance between the first ohmic contact and the field oxide is at least 2 mm.

18. The method according to claim 14, wherein the length of the first ohmic contact extending above the doped region is at least 1 mm.

19. The method according to claim 14, wherein the semiconductor substrate includes a silicon carbide substrate having an upper surface and a bottom surface.

20. The method according to claim 19, further comprising:
forming a drift region of the first conductivity type on the upper surface of the semiconductor substrate;
forming a JFET region of the first conductivity type above the drift region;
forming a base region of the second conductivity type between the JFET region and the source region;
forming a gate oxide above the JFET region, base region, and source region;
forming a channel region of the second conductivity type on the base region and below the gate oxide; and
forming a second ohmic contact in electrical communication with the bottom surface of the semiconductor substrate.
